(19) United States
(12) Patent Application Publication
(10) Pub. No.: US 2026/0068143 A1
(43) Pub. Date: Mar. 5, 2026

(54) WORD LINE STRUCTURE BETWEEN SELECTIVELY TRIMMED STRUCTURES OF A SEMICONDUCTOR DEVICE

(71) Applicant: Micron Technology, Inc., Boise, ID (US)

(72) Inventors: Babak TAHMOURESILERD, Boise, ID (US); Vivek YADAV, Boise, ID (US); Kangle LI, Boise, ID (US); Sanjeev SAPRA, Boise, ID (US)

(21) Appl. No.: 19/252,547

(22) Filed: Jun. 27, 2025

Related U.S. Application Data
(60) Provisional application No. 63/687,375, filed on Aug. 27, 2024.

(51) Int. Cl. H10B 12/00; H10D 64/66

(52) U.S. Cl. CPC H10B 12/488; H10D 64/665; H10D 64/668

(57) ABSTRACT

Implementations described herein relate to various structures, integrated assemblies, and memory devices. In some implementations, an integrated assembly includes a first elongated structure that includes a first series of active area segments alternating with dielectric segments. The integrated assembly includes a second elongated structure including a second series of active area segments alternating with dielectric segments. The integrated assembly includes a word line structure running lengthwise between the first elongated structure and the second elongated structure, wherein widths of the word line structure between the opposing active area segments are different than widths of the word line structure between the opposing dielectric segments.

### CROSS-REFERENCE TO RELATED APPLICATION

This Patent Application claims priority to U.S. Provisional Patent Application No. 63/687,375, filed on Aug. 27, 2024, entitled “WORD LINE STRUCTURE BETWEEN SELECTIVELY TRIMMED STRUCTURES OF ASEMICONDUCTOR DEVICE,” and assigned to the assignee hereof. The disclosure of the prior Application is considered part of and is incorporated by reference into this Patent Application.

### TECHNICAL FIELD

The present disclosure generally relates to semiconductor devices and methods of forming semiconductor devices. For example, the present disclosure relates to a word line structure between selectively trimmed structures of a semiconductor device.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, the electronic device may write, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source. A binary memory device may, for example, include a charged or discharged capacitor. A charged capacitor may, however, become discharged over time through leakage currents, resulting in the loss of the stored information. Some features of volatile memory may offer advantages, such as faster read or write speeds, while some features of non-volatile memory, such as the ability to store data without periodic refreshing, may be advantageous.

### BRIEF DESCRIPTION OF THE DRAWINGS

FIG. 1 is a circuit diagram of an example memory cell described herein.

FIGS. 2A and 2B are diagrammatic views illustrating an example implementation of an integrated assembly at different stages of formation.

FIG. 3 is a flowchart of an example method of forming an integrated assembly or memory device having a word line structure between selectively trimmed structures of a semiconductor device.

FIG. 4 includes diagrammatic views showing formation of a word line structure at example process stages of an example process of forming the word line structure.

FIG. 5 includes diagrammatic views showing formation of a word line structure at example process stages of an example process of forming the word line structure.

FIG. 6 includes diagrammatic views showing formation of a word line structure at example process stages of an example process of forming the word line structure.

FIG. 7 is a diagrammatic view of an example memory device.

### DETAILED DESCRIPTION

Dynamic random access memory (DRAM) technology has continually evolved, with a persistent industry-driven goal of shrinking memory cells to achieve higher densities and improved performance. As the industry moves toward smaller geometries, device performance becomes increasingly susceptible to a variety of challenges. One of the prevalent issues is that of managing resistance within the word line (WL) structures of memory cells. Elevated resistance levels can negatively impact the speed and efficiency of memory operations, degrading overall device performance. Additionally, the miniaturization of devices exacerbates the occurrence of leakage, where unwanted current flows through non-ideal paths, further diminishing the reliability and efficiency of the memory cells.

In the drive toward improvement, managing the resistance of the word line, controlling leakage, and ensuring high-quality interfaces are technical obstacles that require new and innovative processes. Traditional techniques of memory manufacturing struggle to adequately address these heightened resistivity and leakage issues without compromising the integrity of the memory cell structures, especially as the industry approaches the limits of current fabrication methodologies. These technical problems necessitate the development of refined processes tailored to the precise requirements of advanced memory technology, where even marginal improvements in resistance or leakage can translate to substantial gains in device performance and reliability.

Some implementations described herein address the challenge of high word line resistance in a memory device by using techniques that selectively trim active area segments and/or dielectric segments prior to formation of a word line. By selectively trimming the active area segments and/or the dielectric segments, a volume of the word line structure may be increased to reduce word line resistance. Furthermore, and by adopting this selective trimming approach, a surface quality of the active area segments (e.g., silicon) may be improved, in order to improve an interface for gate oxide deposition and to reduce leakage.

In these ways, the techniques improve a performance of the memory device by reducing the word line resistance and improve a reliability of the memory device by reducing leakage. By improving the performance and reliability of the memory device, an amount of resources needed to support a product line using the memory device (e.g., semiconductor manufacturing tools, labor, materials, and/or computing resources) may be conserved.

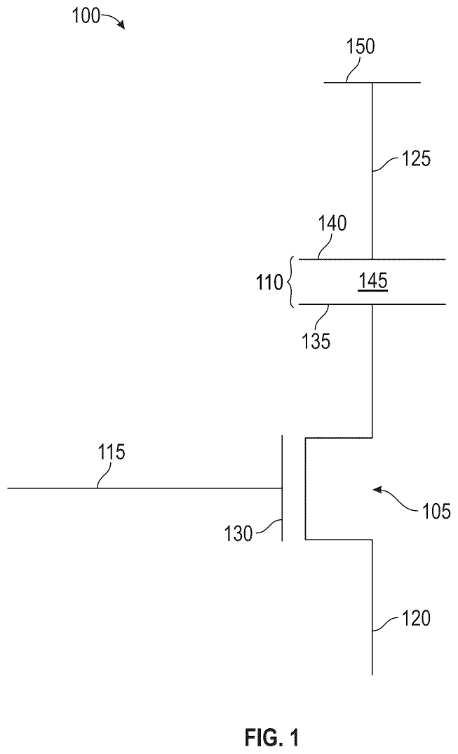

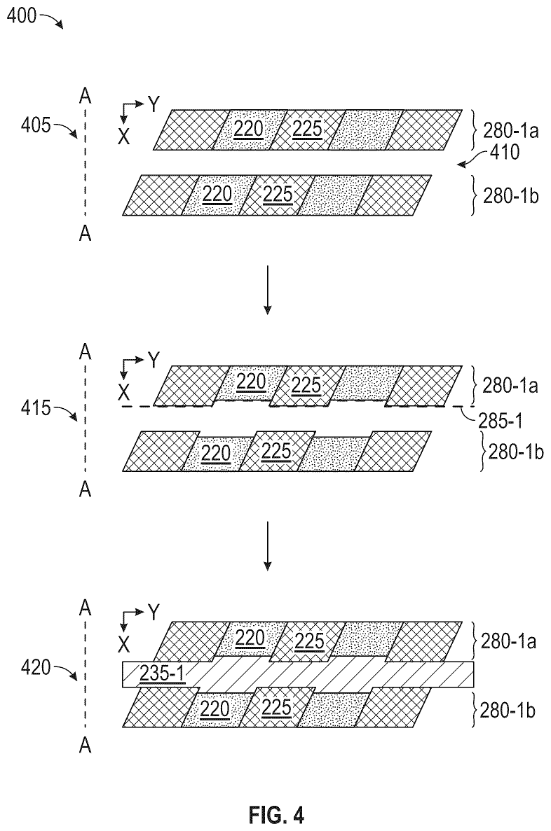

FIG. 1 is a circuit diagram of an example memory cell 100 described herein. In some implementations, the memory cell 100 is a ferroelectric memory cell. Alternatively, the memory cell 100 may be a linear dielectric memory cell or a paraelectric memory cell. As shown in FIG. 1, the memory cell 100 may include a transistor 105 (or another type of selection circuit) and a capacitor 110. The memory cell 100 may be accessed (e.g., written to, read from, and/or erased) using signals on a combination of lines that are coupled to the memory cell 100, shown as an access line 115 (sometimes called a “word line”), a digit line 120 (sometimes called a “bit line”), and a plate line 125. In some implementations, and as described in greater detail in connection with FIGS. 4-7, the access line 115 may be between selectively trimmed active area segments and/or dielectric segments of a semiconductor device.

The transistor 105 (sometimes called an access transistor) may include a gate 130. The capacitor 110 includes a bottom electrode 135 and a top electrode 140 separated by an insulator 145. In some implementations, the capacitor is a ferroelectric capacitor, and the insulator 145 is a ferroelectric insulator that comprises, consists of, or consists essentially of ferroelectric material. Alternatively, the capacitor may be a linear dielectric capacitor, and the insulator 145 may be a linear dielectric insulator that comprises, consists of, or consists essentially of linear dielectric material. Alternatively, the capacitor may be a paraelectric capacitor, and the insulator 145 may be a paraelectric insulator that comprises, consists of, or consists essentially of paraelectric material. When the access line 115 is activated (e.g., when a voltage is applied to the access line 115), the gate 130 coupled to the access line 115 may be activated. When the gate 130 is activated, the transistor 105 couples the digit line 120 to the bottom electrode 135 of the capacitor 110. A state of the memory cell 100 may then be written or read via the digit line 120.

The top electrode 140 of the capacitor 110 may be coupled to the plate line 125 and a cell plate 150. To write to (or program) the memory cell 100, the access line 115 may be activated, and a voltage may be applied across the capacitor 110 by controlling the voltage of the top electrode 140 (via the plate line 125 and/or the cell plate 150) and/or the bottom electrode 135 (via the digit line 120).

To read the memory cell 100 (e.g., a state stored by the capacitor 110), the access line 115 may be activated, and a voltage may be applied to the plate line 125. Applying a voltage to the plate line 125 may cause a change in the stored charge on the capacitor 110. The magnitude of the change in stored charge may depend on the stored state of capacitor 110 (e.g., whether the stored state is a logic “1” state or a logic “0” state). This may or may not induce a threshold change in the voltage of the digit line 120 based on the charge stored on the capacitor 110. The change in voltage or lack of change in voltage of the digit line 120 (or a magnitude of the change in voltage) may be used to determine the stored state of the capacitor 110. For example, if the change in voltage satisfies a threshold, then the read operation indicates that a first state was stored in the capacitor 110, whereas if the change in voltage does not satisfy the threshold, then the read operation determines that a second state was stored in the capacitor 110. In some cases, multiple threshold voltages may be used, such as when the capacitor is capable of storing more than two data states (e.g., for a multi-level cell, a triple-level cell, and so on).

As indicated above, FIG. 1 is provided as an example. Other examples may differ from what is described with respect to FIG. 1.

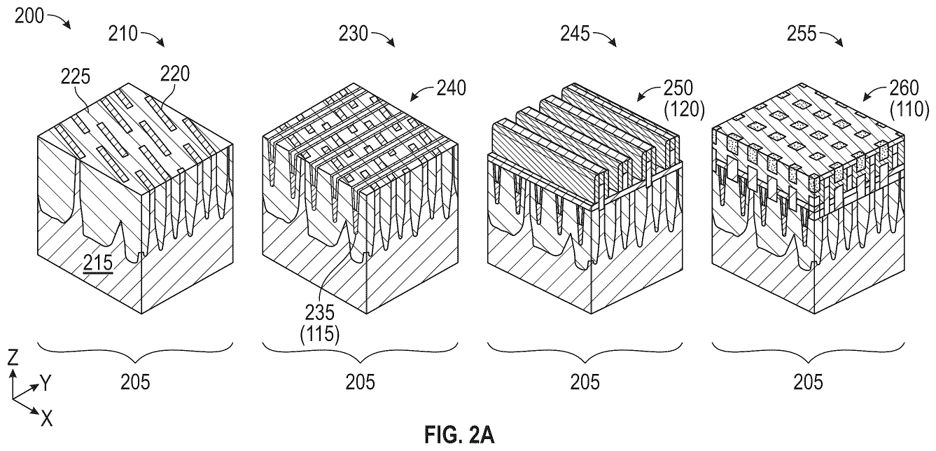

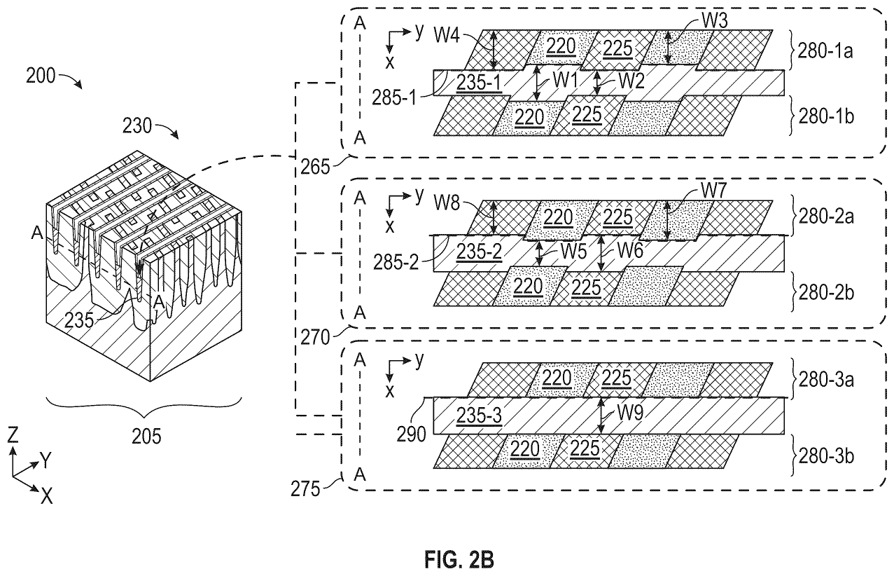

FIGS. 2A and 2B are diagrammatic views illustrating an example implementation 200 of an integrated assembly 205 at different stages of formation. In some implementations, the integrated assembly 205 is a portion of a semiconductor device, such as a DRAM memory device.

As shown in FIG. 2A, and at stage 210, the integrated assembly 205 includes a substrate 215 and a dielectric region 220 that are over and/or on the substrate 215. The substrate 215 may be a semiconductor and may comprise, consist of, or consist essentially of semiconductive material. The semiconductive material may comprise, consist of, or consist essentially of silicon (e.g., polycrystalline silicon) or a type III-V element, among other examples. The dielectric region 220 may include a combination of dielectric layers, where each dielectric layer is an electrical insulator that may comprise, consist of, or consist essentially of insulative material. The insulative material may comprise, consist of, or consist essentially of silicon dioxide, silicon nitride, silicon dioxide, aluminum oxide, hafnium oxide, or titanium dioxide, among other examples.

In some implementations, and as shown in FIG. 2A, active areas 225 may penetrate into and/or through the dielectric region 220. An active area 225 may include a combination of one or more semiconductive layers, where each semiconductive layer may include a semiconductive material as described above. In some implementations, an active area 225 may be doped with a dopant (e.g., an n-type or a p-type dopant) to change a property of a semiconductive layer. Furthermore, an active area 225 may correspond to circuitry of the integrated assembly 205, such as a channel portion of a transistor included in a memory cell of the integrated assembly 205 (e.g., a channel of the transistor 105 of the memory cell 100 of FIG. 1).

As further shown in FIG. 2A, and at stage 230, the integrated assembly 205 includes word line structures 235 below insulative structures 240 (e.g., the word line structures 235 are buried word line structures). A word line structure 235 (e.g., corresponding to the access line 115 of FIG. 1) may include one or more layers of an electrical conductor that may comprise, consist of, or consist essentially of conductive material. The conductive material may comprise, consist of, or consist essentially of a metal (e.g., titanium, tungsten, cobalt, nickel, platinum, and/or ruthenium), a metal composition (e.g., a metal silicide, a metal carbide, and/or a metal nitride, such as titanium nitride or titanium silicon nitride), a silicide, and/or a conductively-doped semiconductor material (e.g., conductively-doped silicon, conductively-doped germanium, and/or conductively-doped gallium arsenide), among other examples. The insulative structures 240 may include one or more layers of an insulative material as described above.

As further shown in FIG. 2A, and at stage 245, the integrated assembly 205 includes bit line structures 250 over the word line structures 235. In some implementations, the bit line structures 250 are oriented orthogonally to the word line structures 235. A bit line structure 250 (e.g., corresponding to the digit line 120 of FIG. 1) may include one or more layers of a conductive material as described above.

As further shown in FIG. 2A, and at stage 255, the integrated assembly 205 includes a capacitor array structure 260 over the bit line structures 250. The capacitor array structure 260 may include an array of capacitors (e.g., corresponding to the capacitor 110 of FIG. 1) and contact structures. The capacitor array structure 260 may include one or more layers of conductive materials and/or insulative materials as described above.

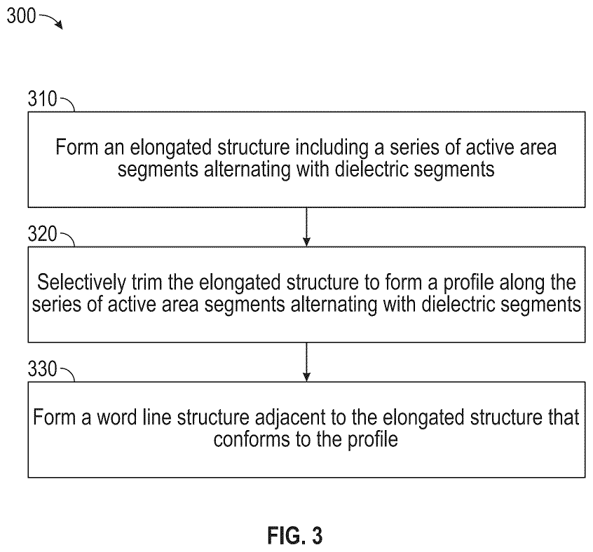

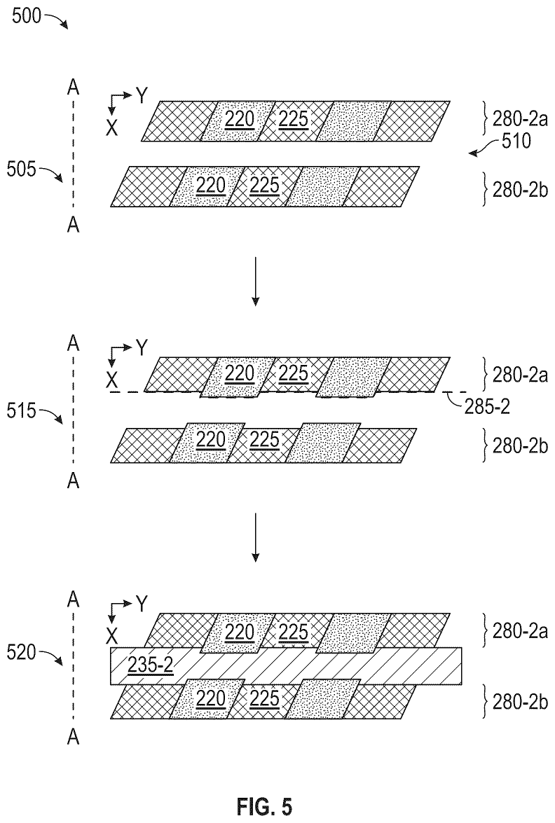

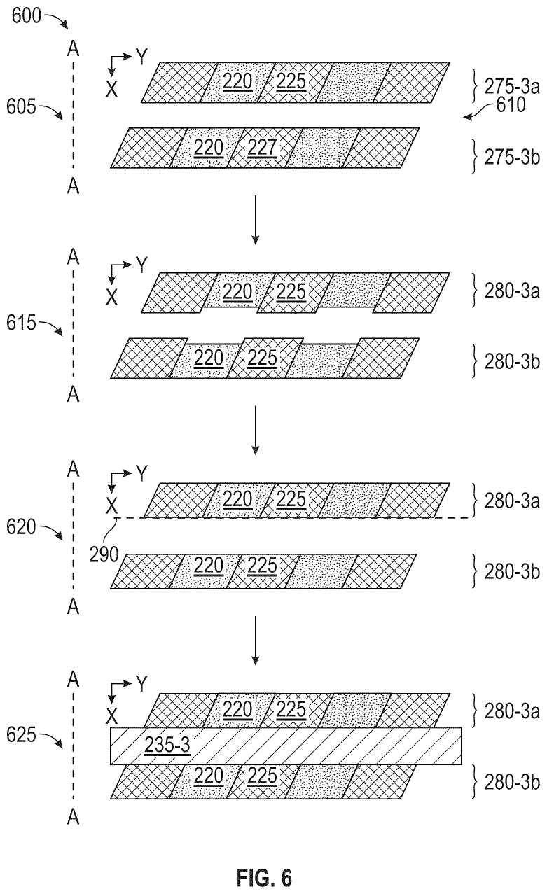

FIG. 2B shows details of example implementations 265, 270, and 275 of a word line structure described herein (e.g., the word line structure 235). Views of implementations 265, 265, and 270 are taken along the section A-A of the integrated assembly 205. Implementation 265 includes a word line structure 235-1 that may be formed using selective etching techniques described in greater detail in connection with FIGS. 3 and 4. Implementation 270 includes a word line structure 235-2 that may be formed using selective etching techniques described in greater detail in connection with FIGS. 3 and 5. Implementation 275 includes a word line structure 235-3 that may be formed using selective etching techniques described in greater detail in connection with FIGS. 3 and 6.

As part of implementation 265, the word line structure 235-1 runs between elongated structures 280-1a and 280-1b. The elongated structures 280-1a and 280-1b may each include a series of segments of the dielectric region 220 alternating with segments of the active areas 225. As part of implementation 265, widths W1 of the word line structure 235-1 between opposing segments of the dielectric region 220 may be greater than widths W2 of the word line structure 235-1 between opposing segments of the active areas 225. Additionally, or alternatively, segments of the dielectric region 220 may have widths W3 (e.g., same approximate widths) that are less than widths W4 (e.g., same approximate widths) of the segments of the active areas 225.

As part of implementation 265, segments of the active areas 225 protrude further towards the word line structure 235-1 than segments of the dielectric region 220, causing surfaces of the active areas 225 and the dielectric region 220 to form a crenellated profile 285-1 (e.g., a non-linear profile, a “zig-zag” profile, or a serpentine profile). As shown in FIG. 2B, the word line structure 235-1 may conform to the crenellated profile 285-1 along the elongated structure 280-1a. Additionally, or alternatively, the word line structure 235-1 may conform to another crenellated profile along an opposite elongated structure (e.g., the elongated structure 280-1b), causing both sides of the word line structure to 235-1 to elongate in a crenellated fashion.

As part of implementation 265, and as shown in FIG. 2B, surfaces of the elongated structure 280-1a across from the word line 235-1 may form an approximately linear profile (e.g., a shallow trench isolation region or another approximately linear structure may be formed along the elongated structure 280-1a across from the word line structure 235-1). Alternatively, and in some implementations, surfaces of the elongated structure 280-1a across from the word line structure 235-1 may form another crenellated profile (e.g., another word line structure may be formed along the elongated structure 280-1a across from the word line structure 235-1).

As part of implementation 270, the word line structure 235-2 runs between elongated structures 280-2a and 280-2b. The elongated structures 280-2a and 280-2b may each include a series of segments of the dielectric region 220 alternating with segments of the active areas 225. As part of implementation 270, widths W5 of the word line structure 235-2 between opposing segments of the dielectric region 220 may be less than widths W6 of the word line structure 235-2 between opposing segments of the active areas 225. Additionally, or alternatively, the segments of the dielectric region 220 may have widths W7 (e.g., same approximate widths) that are greater than a widths W8 (e.g., same approximate widths) of the segments of the active areas 225.

As part of implementation 270, segments of the dielectric region 220 protrude further towards the word line structure 235-2 than segments of the active areas 225, causing surfaces of the dielectric region 220 and the active areas 225 to form a crenellated profile 285-2. As shown in FIG. 2B, the word line structure 235-2 may conform to the crenellated profile 285-2 along the elongated structure 280-2a. Additionally, or alternatively, the word line structure 235-2 may conform to another crenellated profile along an opposite elongated structure (e.g., the elongated structure 280-2b), causing both sides of the word line structure to 235-2 to elongate in a crenellated fashion.

As part of implementation 270, and as shown in FIG. 2B, surfaces of the elongated structure 280-2a across from the word line structure 235-2 may form an approximately linear profile (e.g., an approximately linear structure, such as a shallow trench isolation region, may be formed along the elongated structure 280-2a across from the word line structure 235-2). Alternatively, and in some implementations, surfaces of the elongated structure 280-2a across from the word line structure 235-2 may form another crenellated profile (e.g., another word line structure may be formed along the elongated structure 280-2a across from the word line structure 235-2).

As part of implementation 275, the word line structure 235-3 runs between elongated structures 280-3a and 280-3b. The elongated structures 280-3a and 280-3b may each include a series of segments of the dielectric region 220 alternating with segments of the active areas 225. As part of implementation 270, a width W9 of the word line structure 235-3 between opposing segments of the dielectric region 220 and opposing segments of the active areas 225 is substantially uniform. Further, and as part of implementation 275, the word line structure 235-3 may conform to an approximately linear profile 290 along the elongated structure 280-3a.

As indicated above, FIGS. 2A and 2B are provided as examples. Other examples may differ from what is described with regard to FIGS. 2A and 2B.

As described in connection with FIGS. 1, 2A, and 2B, and in some implementations, an integrated assembly (e.g., the integrated assembly 205) includes a first elongated structure (e.g., the elongated structure 280-1a or 280-2a) including a first series of active area segments (e.g., segments of the active areas 225) alternating with dielectric segments (e.g., segments of the dielectric region 220). The integrated assembly includes a second elongated structure (e.g., the elongated structure 280-1b or the elongated structure 280-2b) including a second series of active area segments (e.g., segments of the active area 225) alternating with dielectric segments (e.g., segments of the dielectric regions 220). The integrated assembly includes a word line structure (e.g., the word line structure 235-1 or the word line structure 235-2) running lengthwise between the first elongated structure and the second elongated structure, wherein widths (e.g., the widths W2 or the widths W6) of the word line structure between the opposing active area segments are different than widths (e.g., the widths W1 or the widths W5) of the word line structure between the opposing dielectric segments.

Additionally, or alternatively and in some implementations, an apparatus (e.g., the integrated assembly 205) includes an elongated structure (e.g., the elongated structure 280-1a or the elongated structure 280-1b) that includes a series of active area segments (e.g., segments of the active areas 225) alternating with dielectric segments (e.g., segments of the dielectric region 220). In some implementations, surfaces of the active area segments and the dielectric segments form a crenellated profile. The apparatus includes a word line structure (e.g., the word line structure 235-1 or the word line structure 235-2) running along the elongated structure, where the word line structure conforms to the crenellated profile.

In these ways, a volume of a word line structure is increased in order to reduce electrical resistance and improve a performance of a semiconductor device including the integrated assembly and/or the apparatus. Furthermore, the word line structure may mitigate leakage issues associated with the integrated assembly, thereby improving reliability of the semiconductor device.

FIG. 3 is a flowchart of an example method 300 of forming an integrated assembly or memory device having a word line structure (e.g., the word line structure 235) between selectively trimmed structures (e.g., the elongated structures 280) of a semiconductor device. In some implementations, one or more process blocks of FIG. 3 may be performed by various semiconductor manufacturing equipment.

As shown in FIG. 3, the method 300 may include forming an elongated structure (e.g., the elongates structure 280) including a series of active area segments (e.g., segments of the active areas 225) alternating with dielectric segments (e.g., segments of the dielectric region 220) (block 310). As further shown in FIG. 3, the method 300 may include selectively trimming the elongated structure to form a profile (e.g., the crenellated profile 285 or the approximately linear profile 290) along the series of active area segments alternating with dielectric segments (block 320). As further shown in FIG. 3, the method 300 may include forming a word line structure (e.g., the word line structure 235) adjacent to the elongated structure that conforms to the profile (block 330).

The method 300 may include additional aspects, such as any single aspect or any combination of aspects described below and/or in connection with one or more other methods described elsewhere herein.

In a first aspect, selectively trimming the elongated structure includes selectively trimming the elongated structure using a wet, vapor etch process.

In a second aspect, alone or in combination with the first aspect, selectively trimming the elongated structure includes determining a target width (e.g., the width W1, the width W2, the width W5, or the width W6) of a segment of the word line structure, and selectively trimming a segment of the elongated structure using at least one of an etch time or an etch chemistry that is varied based on the target width.

In a third aspect, alone or in combination with one or more of the first and second aspects, the profile is a crenellated profile (e.g., the crenellated profile 285-2), and selectively trimming the elongated structure includes selectively trimming the elongated structure using an etchant that etches the active area segments.

In a fourth aspect, alone or in combination with one or more of the first through third aspects, the profile is a crenellated profile (e.g., the crenellated profile 285-1), and selectively trimming the elongated structure includes selectively trimming the elongated structure using an etchant that etches the dielectric segments.

In a fifth aspect, alone or in combination with one or more of the first through fourth aspects, the profile is an approximately linear profile (e.g., the approximately linear profile 290), and selectively trimming the elongated structure includes selectively trimming the elongated structure using a first etchant that etches the active arca segments, and selectively trimming the elongated structure using a second etchant that etches the dielectric segments.

In a sixth aspect, alone or in combination with one or more of the first through fifth aspects, the active area segments comprise silicon, and selectively trimming the elongated structure forms a conditioned silicon surface by repairing damage caused by an exposure of the silicon to a dry etch plasma.

In a seventh aspect, alone or in combination with one or more of the first through sixth aspects, the method 300 includes forming a gate oxide on the conditioned silicon surface.

In an eighth aspect, alone or in combination with one or more of the first through seventh aspects, forming the gate oxide on the conditioned silicon surface includes forming the gate oxide using an atomic layer deposition process.

Although FIG. 3 shows example blocks of the method 300, in some implementations, the method 300 may include additional blocks, fewer blocks, different blocks, or differently arranged blocks than those depicted in FIG. 3. In some implementations, the method 300 may include forming the word line structure 235, an integrated assembly that includes the word line structure 235, any part described herein of the word line structure 235, and/or any part described herein of an integrated assembly that includes the word line structure 235.

FIG. 4 includes diagrammatic views showing formation of a word line structure (e.g., the word line structure 235-1 of implementation 265) at example process stages of an example process 400 of forming the word line structure. In some implementations, the process 400 described below in connection with FIG. 4 may correspond to the method 300 and/or one or more blocks of the method 300. However, the process 400 described below is an example, and other example processes may be used to form the word line structure, an integrated assembly (e.g., the integrated assembly 205) that includes the word line structure, and/or one or more parts of the word line structure and/or the integrated assembly.

As shown in FIG. 4, the process 400 may include a series of operations 405 that forms the elongated structures 280-1a and 280-1b that each include a series of active area segments (e.g., segments of the active areas 225) alternating with dielectric segments (e.g., segments of the dielectric region 220). The series of operations 405 may include forming the active areas 225 by depositing (e.g., growing) a semiconductive material and/or patterning the series of active area segments from the semiconductive material. Additionally, or alternatively, the series of operations 405 may include forming the dielectric regions 220 by depositing (e.g., growing) an insulative material and/or patterning the series of dielectric segments from the insulative material. Additionally, or alternatively, the series of operations 405 may include removing material from the series of active area segments and the series of dielectric segments to form a cavity 410 that defines the elongated structures 280-1a and 280-1b.

As further shown in FIG. 4, the process 400 may further include a series of operations 415 that removes portions of the dielectric segments to form the crenellated profile 285-1 along the elongated structure 280-1a (and/or along the elongated structure 280-1b). In some implementations, removing the portions of the dielectric segments includes using a wet, vapor etchant. Additionally, or alternatively and in some implementations, removing the portions of the dielectric segments includes using an etchant to selectively remove portions of the dielectric segments. In other words, removing the portions may include using a selective etching operation to remove portions of the segments of the dielectric region 220.

As further shown in FIG. 4, the process 400 may further include a series of operations 420 that forms the word line structure 235-1 between the elongated structures 280-1a and 280-1b. Forming the word line structure 235-1 may include depositing (e.g., growing) a conductive material in the cavity 410 between the elongated structures 280-1a and 280-1b.

In some implementations, the process 400 may include a series of operations that forms a dielectric layer between the word line structure 235-1 and surfaces of the elongated structures 280-1a and 280-1b (not shown in FIG. 4). For example, and in some implementations, an atomic layer deposition tool may form an oxide layer (e.g., a gate oxide layer) on surfaces of the active area segments prior to formation of the word line structure 235-1.

As indicated above, the process steps described in connection with FIG. 4 are provided as examples. Other examples may differ from what is described with respect to FIG. 4. The structure shown in FIGS. 4 may be equivalent to the implementation 265 of the word line structure 235-1 described elsewhere herein. In process steps above that describe forming material, such material may be formed, for example, using chemical vapor deposition, atomic layer deposition, physical vapor deposition, or another deposition technique. In process steps above that describe removing material, such material may be removed, for example, using a wet etching technique (e.g., wet chemical etching), a dry etching technique (e.g., plasma etching), an ion etching technique (e.g., sputtering or reactive ion etching), atomic layer etching, or another etching technique.

FIG. 5 includes diagrammatic views showing formation of a word line structure (e.g., the word line structure 235-2 of implementation 270) at example process stages of an example process 500 of forming the word line structure. In some implementations, the process 500 described below in connection with FIG. 5 may correspond to the method 300 and/or one or more blocks of the method 300. However, the process 500 described below is an example, and other example processes may be used to form the word line structure, an integrated assembly (e.g., the integrated assembly 205) that includes the word line structure, and/or one or more parts of the word line structure and/or the integrated assembly.

As shown in FIG. 5, the process 500 may include a series of operations 505 that forms the elongated structures 280-2a and 280-2b that each include a series of active area segments (e.g., segments of the active areas 225) alternating with dielectric segments (e.g., segments of the dielectric region 220). The series of operations 505 may include forming the active areas 225 by depositing (e.g., growing) a semiconductive material and/or patterning the series of active area segments from the semiconductive material. Additionally, or alternatively, the series of operations 505 may include forming the dielectric regions 220 by depositing (e.g., growing) an insulative material and/or patterning the series of dielectric segments from the insulative material. Additionally, or alternatively, the series of operations 505 may include removing material from the series of active area segments and the series of dielectric segments to form a cavity 510 that defines the elongated structures 280-2a and 280-2b.

In some implementations, forming the cavity 510 includes using a dry etch operation. In such implementations, the dry etch operation may damage surfaces of the active area segments.

As further shown in FIG. 5, the process 500 may further include a series of operations 515 that removes portions of the active area segments to form the crenellated profile 285-2 along the elongated structure 280-2a (and/or along the elongated structure 280-2b). In some implementations, removing the portions of the active area segments includes using a wet, vapor etchant. Additionally, or alternatively and in some implementations, removing the portions of the active area segments includes using an etchant to selectively remove portions of the active area segments. In other words, removing the portions may include using a selective etching operation to remove portions of the segments of the active areas 225.

In some implementations, selectively removing the portions of the active area segments may repair damage to surfaces of the active area segments caused by formation of the cavity 510.

As further shown in FIG. 5, the process 500 may further include a series of operations 520 that forms the word line structure 235-2 between the elongated structures 280-2a and 280-2b. Forming the word line structure 235-2 may include depositing (e.g., growing) a conductive material in the cavity 510 between the elongated structures 280-2a and 280-2b.

In some implementations, the process 500 may include a series of operations that forms a dielectric layer between the word line structure 235-2 and surfaces of the elongated structures 280-2a and 280-2b (not shown in FIG. 5). For example, and in some implementations, an atomic layer deposition tool may form an oxide layer (e.g., a gate oxide layer) on surfaces of the active area segments prior to formation of the word line structure 235-2. In such implementations, adhesion of the oxide layer to surfaces of the active area segments may be improved as a result of the selective etching operation described in connection with the series of operations 515.

As indicated above, the process steps described in connection with FIG. 5 are provided as examples. Other examples may differ from what is described with respect to FIG. 5. The structure shown in FIG. 5 may be equivalent to the implementation 270 of the word line structure 235-2 described elsewhere herein. In process steps above that describe forming material, such material may be formed, for example, using chemical vapor deposition, atomic layer deposition, physical vapor deposition, or another deposition technique. In process steps above that describe removing material, such material may be removed, for example, using a wet etching technique (e.g., wet chemical etching), a dry etching technique (e.g., plasma etching), an ion etching technique (e.g., sputtering or reactive ion etching), atomic layer etching, or another etching technique.

FIG. 6 includes diagrammatic views showing formation of a word line structure (e.g., the word line structure 235-3 of implementation 275) at example process stages of an example process 600 of forming the word line structure. In some implementations, the process 600 described below in connection with FIG. 6 may correspond to the method 300 and/or one or more blocks of the method 300. However, the process 600 described below is an example, and other example processes may be used to form the word line structure, an integrated assembly (e.g., the integrated assembly 205) that includes the word line structure, and/or one or more parts of the word line structure and/or the integrated assembly.

As shown in FIG. 6, the process 600 may include a series of operations 605 that forms the elongated structures 280-3a and 280-3b that each include a series of active area segments (e.g., segments of the active areas 225) alternating with dielectric segments (e.g., segments of the dielectric region 220). The series of operations 605 may include forming the active areas 225 by depositing (e.g., growing) a semiconductive material and/or patterning the series of active area segments from the semiconductive material. Additionally, or alternatively, the series of operations 605 may include forming the dielectric regions 220 by depositing (e.g., growing) an insulative material and/or patterning the series of dielectric segments from the insulative material. Additionally, or alternatively, the series of operations 605 may include removing material from the series of active area segments and the series of dielectric segments to form a cavity 510 that defines the elongated structures 280-3a and 280-3b.

In some implementations, forming the cavity 610 includes using a dry etch operation. In such implementations, the dry etch operation may damage surfaces of the active area segments.

As further shown in FIG. 6, the process 600 may further include a series of operations 615 that removes portions of the dielectric segments. In some implementations, removing the portions of the dielectric segments includes using a wet, vapor etchant. Additionally, or alternatively and in some implementations, removing the portions of the dielectric segments includes using an etchant to selectively remove portions of the dielectric segments. In other words, removing the portions may include using a selective etching operation (e.g., a first selective etching operation) to remove portions of segments of the dielectric region 220.

As further shown in FIG. 6, the process 600 may further include a series of operations 620 that removes portions of the active area segments to form the approximately linear profile 290 along the elongated structure 280-3a (and/or along the elongated structure 280-3b). In some implementations, removing the portions of the active area segments includes using a wet, vapor etchant. Additionally, or alternatively and in some implementations, removing the portions of the active area segments includes using an etchant to selectively remove portions of the active area segments. In other words, removing the portions may include using a selective etching operation to remove portions of the segments of the active areas 225. In other words, removing the portions may include using a selective etching operation (e.g., a second selective etching operation) to remove portions of segments of the active areas 225.

In some implementations, selectively removing the portions of the active area segments may repair damage to surfaces of the active area segments caused by formation of the cavity 610.

As further shown in FIG. 6, the process 600 may further include a series of operations 625 that forms the word line structure 235-3 between the elongated structures 280-3a and 280-3b. Forming the word line structure 235-3 may include depositing (e.g., growing) a conductive material in the cavity 610 between the elongated structures 280-3a and 280-3b.

In some implementations, the process 600 may include a series of operations that forms a dielectric layer between the word line structure 235-3 and surfaces of the elongated structures 280-3a and 280-3b (not shown in FIG. 6). For example, and in some implementations, an atomic layer deposition tool may form an oxide layer (e.g., a gate oxide layer) on surfaces of the active area segments prior to formation of the word line structure 235-3. In such implementations, adhesion of the oxide layer to surfaces of the active area segments may be improved as a result of the selective etching operation described in connection with the series of operations 615.

As indicated above, the process steps described in connection with FIG. 6 are provided as examples. Other examples may differ from what is described with respect to FIG. 6. The structure shown in FIG. 6 may be equivalent to the implementation 275 of the word line structure 235-3 described elsewhere herein. In process steps above that describe forming material, such material may be formed, for example, using chemical vapor deposition, atomic layer deposition, physical vapor deposition, or another deposition technique. In process steps above that describe removing material, such material may be removed, for example, using a wet etching technique (e.g., wet chemical etching), a dry etching technique (e.g., plasma etching), an ion etching technique (e.g., sputtering or reactive ion etching), atomic layer etching, or another etching technique.

As described in connection with FIGS. 4-6, one or more selective etching operations may be used to increase a width and/or a volume of a word line structure (e.g., the word line structure 235-1, the word line structure 235-2, and/or the word line structure 235-3). By increasing the volume of the word line structure, a resistivity of the word line structure may be reduced in order to improve a performance of a semiconductor device including the word line structure.

Additionally, or alternatively and as described in connection with FIGS. 5 and 6, a selective etching process may repair damage to a surface of an active area segment (e.g., a segment of the active areas 225) caused during formation of a cavity (e.g., the cavity 510 and/or the cavity 610) adjacent to an elongated structure (e.g., the elongated structure 280-2b and/or the elongated structure 280-3b). Repairing the damage to the surface of the active area segment may promote adhesion of a dielectric layer to the active arca segment, to improve a reliability of the semiconductor device.

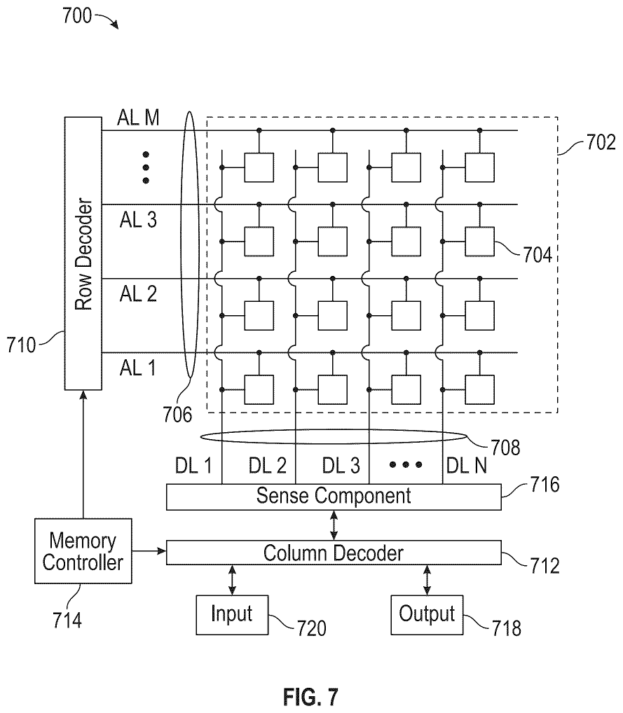

FIG. 7 is a diagrammatic view of an example memory device 700. The memory device 700 may include a memory array 702 that includes multiple memory cells 704. A memory cell 704 is programmable or configurable into a data state of multiple data states (e.g., two or more data states). For example, a memory cell 704 may be set to a particular data state at a particular time, and the memory cell 704 may be set to another data state at another time. A data state may correspond to a value stored by the memory cell 704. The value may be a binary value, such as a binary 0 or a binary 1, or may be a fractional value, such as 0.5, 1.5, or the like. A memory cell 704 may include a capacitor to store a charge representative of the data state. For example, a charged and an uncharged capacitor may represent a first data state and a second data state, respectively. As another example, a first level of charge (e.g., fully charged) may represent a first data state, a second level of charge (e.g., fully discharged) may represent a second data state, a third level of charge (e.g., partially charged) may represent a third data state, and so on.

Operations such as reading and writing (i.e., cycling) may be performed on memory cells 704 by activating or selecting the appropriate access line 706 (shown as access lines AL 1 through AL M) and digit line 708 (shown as digit lines DL 1 through DL N). An access line 706 may also be referred to as a “row line” or a “word line,” and a digit line 708 may also be referred to a “column line” or a “bit line.” Activating or selecting an access line 706 or a digit line 708 may include applying a voltage to the respective line. An access line 706 and/or a digit line 708 may comprise, consist of, or consist essentially of a conductive material, such as a metal (e.g., copper, aluminum, gold, titanium, or tungsten) and/or a metal alloy, among other examples. In FIG. 7, each row of memory cells 704 is connected to a single access line 706, and each column of memory cells 704 is connected to a single digit line 708. By activating one access line 706 and one digit line 708 (e.g., applying a voltage to the access line 706 and digit line 708), a single memory cell 704 may be accessed at (e.g., is accessible via) the intersection of the access line 706 and the digit line 708. The intersection of the access line 706 and the digit line 708 may be called an “address” of a memory cell 704.

In some implementations, the logic storing device of a memory cell 704, such as a capacitor, may be electrically isolated from a corresponding digit line 708 by a selection component, such as a transistor. The access line 706 may be connected to and may control the selection component. For example, the selection component may be a transistor, and the access line 706 may be connected to the gate of the transistor. Activating the access line 706 results in an electrical connection or closed circuit between the capacitor of a memory cell 704 and a corresponding digit line 708. The digit line 708 may then be accessed (e.g., is accessible) to either read from or write to the memory cell 704.

A row decoder 710 and a column decoder 712 may control access to memory cells 704. For example, the row decoder 710 may receive a row address from a memory controller 714 and may activate the appropriate access line 706 based on the received row address. Similarly, the column decoder 712 may receive a column address from the memory controller 714 and may activate the appropriate digit line 708 based on the column address.

Upon accessing a memory cell 704, the memory cell 704 may be read (e.g., sensed) by a sense component 716 to determine the stored data state of the memory cell 704. For example, after accessing the memory cell 704, the capacitor of the memory cell 704 may discharge onto its corresponding digit line 708. Discharging the capacitor may be based on biasing, or applying a voltage, to the capacitor. The discharging may induce a change in the voltage of the digit line 708, which the sense component 716 may compare to a reference voltage (not shown) to determine the stored data state of the memory cell 704. For example, if the digit line 708 has a higher voltage than the reference voltage, then the sense component 716 may determine that the stored data state of the memory cell 704 corresponds to a first value, such as a binary 1. Conversely, if the digit line 708 has a lower voltage than the reference voltage, then the sense component 716 may determine that the stored data state of the memory cell 704 corresponds to a second value, such as a binary 0. The detected data state of the memory cell 704 may then be output (e.g., via the column decoder 712) to an output component 718 (e.g., a data buffer). A memory cell 704 may be written (e.g., set) by activating the appropriate access line 706 and digit line 708. The column decoder 712 may receive data, such as input from input component 720, to be written to one or more memory cells 704. A memory cell 704 may be written by applying a voltage across the capacitor of the memory cell 704.

The memory controller 714 may control the operation (e.g., read, write, re-write, refresh, and/or recovery) of the memory cells 704 via the row decoder 710, the column decoder 712, and/or the sense component 716. The memory controller 714 may generate row address signals and column address signals to activate the desired access line 706 and digit line 708. The memory controller 714 may also generate and control various voltages used during the operation of the memory array 702.

In some implementations, the memory device 700 includes the word line structure 235 and/or the integrated assembly 205 that includes the word line structure 235. For example, the memory array 702 may include the word line structure 235 and/or the integrated assembly 205 that includes the word line structure 235. Additionally, or alternatively, the memory cell 704 may include a memory cell described elsewhere herein.

As indicated above, FIG. 7 is provided as an example. Other examples may differ from what is described with respect to FIG. 7.

In some implementations, an integrated assembly includes a first elongated structure, comprising: a first series of active area segments alternating with dielectric segments; a second elongated structure, comprising: a second series of active arca segments alternating with dielectric segments; and a word line structure running lengthwise between the first elongated structure and the second elongated structure, wherein widths of the word line structure between opposing active area segments are different than widths of the word line structure between opposing dielectric segments.

In some implementations, an apparatus includes an elongated structure, comprising: a series of active area segments alternating with dielectric segments, wherein surfaces of the active area segments and the dielectric segments form a crenellated profile; and a word line structure running along the elongated structure, wherein the word line structure conforms to the crenellated profile.

In some implementations, a method includes forming an elongated structure including a series of active area segments alternating with dielectric segments; selectively trimming the elongated structure to form a profile along the series of active area segments alternating with dielectric segments; and forming a word line structure adjacent to the elongated structure that conforms to the profile.

The foregoing disclosure provides illustration and description but is not intended to be exhaustive or to limit the implementations to the precise forms disclosed. Modifications and variations may be made in light of the above disclosure or may be acquired from practice of the implementations described herein.

Each of the illustrated x-axis, y-axis, and z-axis is substantially perpendicular to the other two axes. In other words, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like. All ranges described herein are inclusive of numbers at the ends of those ranges, unless specifically indicated otherwise.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. An integrated assembly, comprising:
a first elongated structure, comprising:
a first series of active area segments alternating with dielectric segments;
a second elongated structure, comprising:
a second series of active area segments alternating with dielectric segments; and
a word line structure running lengthwise between the first elongated structure and the second elongated structure,
wherein widths of the word line structure between opposing active area segments are different than widths of the word line structure between opposing dielectric segments.

2. The integrated assembly of claim 1, wherein the widths of the word line structure between the opposing active area segments are greater than the widths of the word line structure between the opposing dielectric segments.

3. The integrated assembly of claim 1, where the widths of the word line structure between the opposing active area segments are less than the widths of the word line structure between the opposing dielectric segments.

4. The integrated assembly of claim 1, wherein the word line structure comprises:
tungsten, or
titanium nitride.

5. The integrated assembly of claim 1, wherein the word line structure comprises:
conductively-doped silicon, or silicide.

6. An apparatus, comprising:
an elongated structure, comprising:
a series of active area segments alternating with dielectric segments,
wherein surfaces of the active area segments and the dielectric segments form a crenellated profile; and
a word line structure running along the elongated structure,
wherein the word line structure conforms to the crenellated profile.

7. The apparatus of claim 6, wherein each of the active area segments protrudes further towards the word line structure than the dielectric segments.

8. The apparatus of claim 6, wherein each of the dielectric segments protrudes further towards the word line structure than the active area segments.

9. The apparatus of claim 6, wherein the active area segments comprise:
silicon.

10. The apparatus of claim 6, wherein the active area segments comprise:
a type III-V element.

11. The apparatus of claim 6, wherein the dielectric segments comprise:
silicon dioxide,
silicon nitride,
aluminum oxide,
hafnium oxide, or
titanium dioxide.

12. A method, comprising:
forming an elongated structure including a series of active area segments alternating with dielectric segments;
selectively trimming the elongated structure to form a profile along the series of active area segments alternating with dielectric segments; and
forming a word line structure adjacent to the elongated structure that conforms to the profile.

13. The method of claim 12, wherein selectively trimming the elongated structure includes:
selectively trimming the elongated structure using a wet, vapor etch process.

14. The method of claim 12, wherein selectively trimming the elongated structure includes:
determining a target width of a segment of the word line structure; and
selectively trimming a segment of the elongated structure at least one of an etch time or an etch chemistry that is varied based on the target width.

15. The method of claim 12, wherein the profile is a crenellated profile, and
wherein selectively trimming the elongated structure includes:
selectively trimming the elongated structure using an etchant that etches the active area segments.

16. The method of claim 12, wherein the profile is a crenellated profile, and
wherein selectively trimming the elongated structure includes:
selectively trimming the elongated structure using an etchant that etches the dielectric segments.

17. The method of claim 12, wherein the profile is an approximately linear profile, and wherein selectively trimming the elongated structure includes:
selectively trimming the elongated structure using a first etchant that etches the active area segments, and
selectively trimming the elongated structure using a second etchant that etches the dielectric segments.

18. The method of claim 12, wherein the active area segments comprise silicon, and
wherein selectively trimming the elongated structure forms a conditioned silicon surface by repairing damage caused by an exposure of the silicon to a dry etch plasma.

19. The method of claim 18, further comprising:
forming a gate oxide on the conditioned silicon surface.

20. The method of claim 19, wherein forming the gate oxide on the conditioned silicon surface includes:
forming the gate oxide using an atomic layer deposition process.
